(19) United States
(12) Patent Application Publication
(10) Pub. No.: US 2006/0278962 A1
(43) Pub. Date: Dec. 14, 2006

(54) Microelectronic loop packages

(75) Inventor: David Gibson, Lake Oswego, OR (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 11/321,378

(22) Filed: Dec. 29, 2005

Related U.S. Application Data
(60) Provisional application No. 60/688,997, filed on Jun. 9, 2005.

(51) Int. Cl. H01L 23/495

(52) U.S. Cl. 257/668

(57) ABSTRACT

A microelectronic package including a dielectric element having a fold, a first run and a second run. The dielectric element also includes a first region on the first run, and a second region on the second run. The first and second runs define a cavity which has a first microelectronic device disposed within the cavity. The microelectronic package further includes a plurality of traces disposed on the dielectric element, wherein at least some of the traces are composite traces. The composite traces include a first portion extending in the first region and having a first connection point in the first region, and a second portion extending in the second region and having a second connection point in the second region, with the connection points being outside of the fold. The first connection points are connected to the second connection points to form the composite traces.

### CROSS-REFERENCE TO RELATED APPLICATIONS

The present application claims the benefit of the filing date of U.S. Provisional Patent Application Ser. No. 60/688,997, filed on Jun. 9, 2005, the disclosure of which is hereby incorporated by reference herein.

### BACKGROUND OF THE INVENTION

Certain microelectronic packages are made using a sheet-like element incorporating a dielectric layer and mounting terminals disposed on this structure. Some or all of the terminals are connected to the microelectronic device to be packaged. In many cases, the active microelectronic device such as a semiconductor chip is covered by an encapsulant. The encapsulant commonly is molded in place on the dielectric layer so that the mass of encapsulant has a preselected shape, and so that the encapsulant covers the microelectronic device. The encapsulant may also cover features such as wire bonds which connect the actual chip to the terminals. Such a package may be mounted on a circuit panel such as a circuit board by bonding or otherwise connecting the mounting terminals to contact pads on the circuit board.

Various proposals have been advanced for stacking plural chips one above the other in a common package. One such arrangement includes a substrate having a dielectric structure substantially larger in area than the area of a single microelectronic device or chip. Several microelectronic devices are mounted to the substrate in different areas of the substrate and the substrate is folded so that the various microelectronic devices are stacked one above the other and so that the mounting terminals on the substrate are disposed at the bottom of the stack. Typically, the substrate has electrically conductive traces extending along the dielectric structure. These traces interconnect the microelectronic devices with one another, with the mounting materials or both in the completed structure. In one such structure, the substrate is folded into a serpentine configuration so that the microelectronic devices are stacked one above the other.

If the substrate is folded in precisely the right configuration, the various microelectronic devices will be disposed in the correct locations, one above the other. The entire package can be placed in an area of the circuit board only slightly larger than the area occupied by a single microelectronic device. However, inaccuracies in folding the substrate can cause parts of the package to lie in positions different from their intended position relative to the mounting terminals. This effectively increases the overall size of the package. Neighboring components mounted to the circuit board must be located at a larger distance from the stack so as to provide clearance sufficient to accommodate this internal misalignment within the stack. Moreover, the piece-to-piece differences between individual packages caused by folding inaccuracies can complicate the task of handling and feeding the stacked packages during automated assembly operations as, for example, during mounting to the circuit panel.

As disclosed in commonly assigned U.S. Pat. No. 6,225,688, the disclosure of which is hereby incorporated by reference herein, a folding operation may be performed using a substrate having a plurality of microelectronic devices, and also having connection pads. After folding, the mounting terminals of the substrate lie on the bottom of the folded structure, whereas the connection pads lie on the top of the folded structure. Another assembly having a folded substrate is mounted on top of the folded structure and connected to the folded structure through the connection pads. Also, the connection pads can be used as test terminals for testing the folded structure before or after mounting the same to a circuit panel.

Inaccuracies in folding substrates places connection terminals on the substrate at a position other than their intended position. If an additional microelectronic element or assembly is mounted on top of the folded structure using the connection terminals, the additional microelectronic element will also be displaced from its intended position, further increasing the overall size of the package. Also, displacement of the connecting terminals from their intended position can complicate the tasks of connecting an additional element to the connection terminals and the task of engaging the connecting terminals with a test fixture during a testing operation.

An additional concept of a stack of multiple fold packages is disclosed in commonly-assigned U.S. patent application Ser. No. 10/281,550, the disclosure of which is hereby incorporated by reference herein. A solder ball connect may be used between ends opposite the fold.

An additional folding technique is disclosed in commonly-assigned U.S. patent application Ser. No. 10/654,375, the disclosure of which is hereby incorporated by reference herein. A folding operation may be formed using a substrate having a first portion, a central portion and a second portion, and having traces extending from the central portion to terminals on the first and second portions. Prior to folding, a microelectronic device is mounted on the central portion of the substrate and connected to the traces. The first portion and second portion are folded over the central portion and over the microelectronic device, thereby forming two folds at opposite sides of the package. The terminals on the first and second portions cooperatively define an array of terminals which can be used to mount an additional electronic element. The traces extending across both folds of the substrate increase the routing ability of the package so that a large number of interconnections can be made between the microelectronic device mounted on the central portion of the substrate and the terminal array. However, the folding operation should be carefully controlled so that the first and second portions are aligned with one another. This is desirable so that the terminals included in the terminal array are properly positioned relative to one another. This is particularly important where a single additional microelectronic device or package is to be connected to the entire array.

Thus, still further improvements would be desirable.

### SUMMARY OF INVENTION

One embodiment of the present invention relates to a microelectronic package including a dielectric element having a fold, a first run and a second run, the first run and the second run defining a cavity. The dielectric element may also include a first region on the first run outside of the fold and a second region on the second run outside of the fold.

The microelectronic package may also include a first microelectronic device disposed within the cavity and a plurality of traces. The traces being disposed on the dielectric element with at least some of the traces being composite traces. Each of the composite traces includes a first portion extending in the first region and having a first connection point in the first region. Each composite trace also includes a second portion extending in the second region and a second connection point in the second region. The connection points are preferably outside of the fold and at least some of the first connection points are connected to at least some of the second connection points.

The first connection points and second connection points may include connections that are comprised of masses of bonding material or wire bonds. The microelectronic package may include a circuit panel that is connected to mounting terminals, disposed on the first run or second run. The package may also include an additional microelectronic element connected to at least some of the plurality of connection terminals. The additional microelectronic element may even be a separate microelectronic package.

The plurality of traces of the package may include fold traces that extend across the fold of the package between the first and second regions.

The present invention also includes a method of making a microelectronic package. In one preferred embodiment the method includes the steps of folding a dielectric substrate so as to form a fold. The substrate may include first and second trace portions in first and second regions of the substrate. The first and second regions facing one another so as to define first and second runs of the folded substrate. Next, the first and second trace portions are connected to one another outside of the fold so as to form composite traces.

In certain embodiments the substrate may have fold-side traces in a central region. After the step of folding the substrate is performed so as to bend the central region, the fold-side traces extend between the first and second runs.

### DESCRIPTION OF DRAWINGS

FIG. 1 is a plan view of one embodiment of the present invention at a stage in A method of assembly;

FIG. 2 is a cross-sectional view of the apparatus of FIG. 1;

FIG. 3 is a cross-sectional view of the embodiment of FIG. 1 at a later stage in the method of assembly;

FIG. 4 is a cross-sectional view of the embodiment of FIG. 1 at a later stage in the method of assembly;

FIGS. 5-7 are blown up views of various embodiments of the present invention;

FIG. 8 is a cross-sectional view of an alternate embodiment of the present invention;

FIG. 9 is a cross-sectional view of an alternate embodiment of the present invention;

FIG. 10 is a cross-sectional view of an alternate embodiment during a method of assembly;

FIG. 11 is a cross-sectional view of the embodiment of FIG. 10 at a later stage of the assembly;

FIG. 12 is a cross-sectional view of an alternate embodiment of the present invention; and

FIGS. 13 and 14 are perspective views according to one embodiment of the present invention at various stages of assembly.

The method may also include the step of mounting a first microelectronic device to the substrate and connecting the first microelectronic device to at least some of the first trace portions prior to the folding step. The folding step being performed so as to position the first microelectronic device in a cavity between the runs.

### DETAILED DESCRIPTION

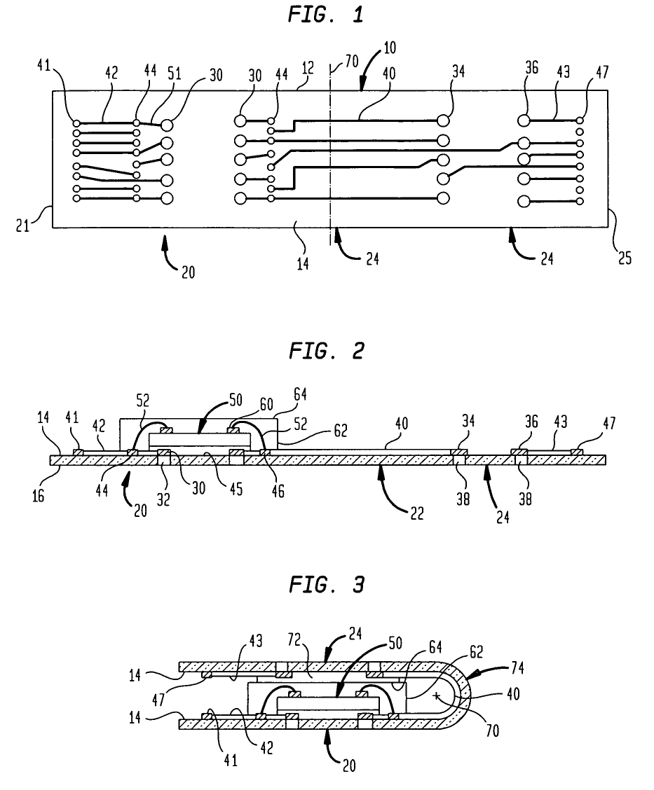

A device in accordance with one embodiment of the present invention includes a substrate 10 (FIG. 1) having a dielectric layer 12 with an interior surface 14 and exterior surface 16 (FIG. 2). Substrate 10 may be formed from any flexible dielectric material as, for example, one or more layers of a dielectric such as polyimide, BT, or flexiblized epoxy. Layers of other dielectric materials may also be used. The dielectric layer typically has a thickness of about 20-100 microns. The substrate 10 includes a first region 20 defining a first end 21, a central portion 22 and a second region 24 defining a second end 25. The first region 20 and second region 24 may comprise more than two-thirds of the substrate 10.

A set of electrically-conductive mounting terminals 30 is disposed in the first region 20 of the substrate 10. In the embodiment of FIG. 1, mounting terminals 30 are disposed at the interior surface 14 of the substrate and exposed to the exterior surface 16 through holes or vias 32 (FIG. 2) extending through the substrate. A set of device pads 44 is also disposed in the first region 20 of the substrate. Some or all of the device pads 44 are connected to some or all of the mounting terminals 30 by short stub traces 31. A first set of connection terminals 34 and a second set of connection terminals 36 are disposed in the second region 24 of the substrate. Connection terminals 34 and 36 are exposed to the exterior surface 16 of the substrate through holes 38. A set of traces 40, referred to herein as “fold-side traces”, extend from the first region 20, across center region 21 to the second region 22. At least some of the fold-side traces 40 are connected to some or all of the device pads 44, to some or all of the mounting terminals 30, or both. Some or all of the fold-side traces 40 are also connected to connection terminals 34 of the first set, to connection terminals 36 of the second set, or both.

A first set of trace portions 42 extend within the first region 20. The trace portions 42 of the first set have first connection points 41 disposed in the first region 20, adjacent first end 21. Some or all of the trace portions 42 of the first set are connection to device pads 44, to mounting terminals 30, or both.

A second set of trace portions 43 extend within the second region 24 of the substrate. Trace portions 43 have second connection points 47 disposed adjacent the second end 25 of the substrate. Second connection points 47 are exposed to the exterior surface 16 of the substrate through holes in the substrate. Some or all of trace portions 43 are connected to connection terminals 36, to connection terminals 34, or both. In the unassembled state depicted in FIGS. 1 and 2, the first set of trace portions 42 are not connected or attached to the second set of trace portions 43.

Only a few of the traces and trace portions are depicted in FIGS. 1 and 2 for clarity of illustration. None of the drawings are to scale and various parts shown may be enlarged for illustration purposes. The conductive features such as terminals 30, 34 and 36, fold-side traces 40, and trace portions 42 and 43 desirably are formed as a single layer of metallic features from a conventional metal of the type commonly used in flexible circuitry as, for example, copper, gold, alloys thereof, or combinations thereof. The metallic features may be formed by selective deposition such as plating or by selective removal from a layer, as by etching. The techniques commonly employed to make flexible circuitry can be employed in fabrication of substrate 10 and metallic features thereon. The substrate may include additional features as, for example, one or more additional layers of traces of electrically-conductive planes such as metallic layers which can serve as a ground or power planes and which cooperate with traces to form controlled impedance strip lines.

In an assembly process, a microelectronic element 50 (FIG. 2) such as a semiconductor chip, is mounted to the interior surface 14 of the substrate in the first region 20. In the embodiment shown, the microelectronic element 50 overlies some or all of the mounting terminals 30. The microelectronic element 50 is preferably attached to the substrate 10 utilizing an adhesive 45. Adhesive 45 may be a conventional die attach material, or a compliant material which permits appreciable movement of the microelectronic element and substrate. Element 50 is electrically connected to at least some of the conductive features on the substrate as, for example, by wire bonding using fine wires 52 to connect contacts 60 on the chip to device pads 44. The microelectronic element 50 and bonding wires 52 desirably are protected by an overmolding 62. Essentially any material commonly used as a protective overmolding material in an electronic packing can be employed. The overmolding 62 forms a top surface 64 for the microelectronic element 50.

In the+ next step of the manufacturing process, the substrate 10 is folded over upon itself by bending generally around an axis 70 (FIG. 1) extending across the center region 22 so as to form a fold 74 (FIG. 3) in the center region. Once the substrate is folded, the second region 24 of the substrate 10 overlies the first region of the substrate, with the interior surface 14 of the second region 24 facing downwardly towards the microelectronic element 50 and towards the first region 20 of the substrate. In the folded condition, connection terminals 34 and 36 overlie microelectronic element 50. In this condition, the first region 20 of the substrate forms a first run located below the microelectronic element 50, whereas the second region 24 forms and a second run located above the microelectronic element 50. The second run 24 desirably is fastened in place by an adhesive 72 disposed between the interior surface of the substrate and the top surface 64 of the microelectronic element, defined by overmolding 62. The adhesive may be applied to the overmolding or to the substrate prior to folding.

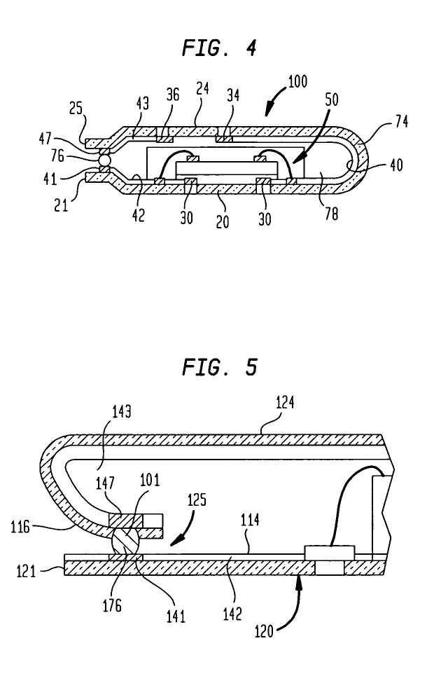

During or after the folding operation, each first connection point 41 and in connected to the overlying second connection point 47, thereby connecting each first trace portion 42 with one of the second trace portions 43 so as to form composite traces. As shown in FIG. 4 the connections between the trace portions are remote from fold 74. These connections may be made by bonding the connection points to one another using masses 76 of a bonding material such as a solder. Conventional techniques such as machine-vision controlled robotics may be used to align the connection points with one another. Also, the ends 21 and 25 of the dielectric layer may be provided with fiducial marks (not shown) to facilitate registration. In a further alternative, the ends may be provided with holes (not shown), and the holes may be engages with alignment pins on a fixture. As also shown in FIG. 4, the ends 21 and 25 may be squeezed together so as to bring the connection points 41 and 47 into proximity with one another for bonding. The bonding material masses may be applied to the connection points prior to folding. In a variant of this procedure, the connection points are provided with bonding materials such as eutectic bonding or diffusion bonding compositions during fabrication of the substrate, so that no separate bonding material is required. In a further variant, a layer of an anisotropic conductive material is applied between the connection points 41 and 47, typically by applying the material to one set of connection points prior to folding. The anisotropic conductive material electrically connects each connection point 41 with the overlying connection point 47.

In the completed package (FIG. 4), runs 20 and 24 define a cavity 78 housing the microelectronic element 50. Some of the connection terminals 34 and 36 on the top run 24 are connected to conductive features such as mounting terminals 30 on the bottom run 20, and to microelectronic element 50, by the fold-side traces 40. Others of the connection terminals 34 and 36 on the top run are connected to the mounting terminals 30 and to microelectronic element 50 by the composite traces incorporating trace portions 42 and 43. The composite traces extend between the top and bottom runs on the side of the package remote from the fold. Because the fold-side traces and the composite traces provide routing on both sides of the package, a large number of interconnections can be provided. However, because the first connection terminals 34 and second connection terminals 36 are all formed on the same portion of the substrate, these terminals are inherently well-aligned with one another in an array.

A package according to a further embodiment of the invention (FIG. 5) is similar to the package discussed above with reference to FIGS. 1-4, except that the second end 125 of the dielectric element is bent over so that the outer surface 116 of the dielectric element at second end 125 faces the inner surface 114 of the dielectric element at first end 121 of the package substrate. The connection points 147 of second trace portions 143 are exposed to the outer surface 116 through holes 101 in the substrate, so that these connection points can be bonded to the connection points 41 of first trace portions 142, as by bonding material masses 176. Here again, the composite traces formed by connecting the trace portions interconnect features on the lower run 120 and upper run 124 at the side of the package remote from the fold (not shown).

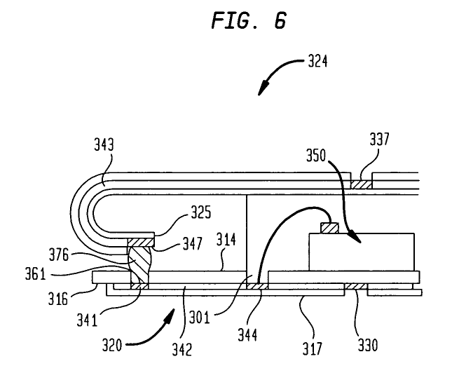

In a further embodiment (FIG. 6), the metallic features of the package substrate, including first trace portions 342, second trace portions 343 and fold-side traces (not shown) are formed on the exterior surface 316 of the package substrate instead of on the interior surface 314. A solder mask layer 317 is provided over the metallic features, with appropriate apertures to expose the mounting terminals 330 on the lower run 320, connection terminals 334 on the upper run 324 and the connection points 347 of the second trace portions. Holes 301 are provided in the dielectric substrate to expose the device pads 344 to the interior surface for connection to the microelectronic device 350. Holes 361 expose the connection points 341 of first trace portions 342 to the interior surface. Here again, the second end 325 of the substrate is bent as discussed above with reference to FIG. 5 so that an electrical connection may be made between traces 342 and 343, as by bonding material masses 376 or other techniques as discussed above.

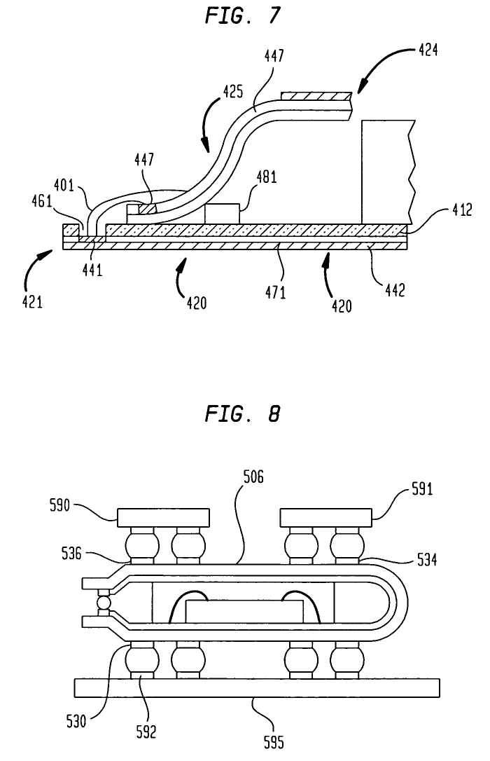

A package according to a further embodiment of the present invention, as shown in FIG. 7, is similar to the package of FIG. 6 in that the package of FIG. 7 also has its conductive features, including trace portions 442 and 443 are disposed on the exterior surface of substrate 412. In the package of FIG. 7, that portion of the substrate adjacent second end 425 is turned outward, so that the exterior or trace-bearing surface, and hence the connection points 447 of second trace portions 443 in the top run 424 face upwardly, away from the bottom run 420. The second end is secured to the bottom run, as by an adhesive 481. Once the runs are proximate to one another, the connection points 447 of trace portions 443 are electrically connected to traces 442 by wire bonds 401. To provide access for wire bonding, connection points 447 are left uncovered by the solder mask layer 471 on the exterior surface, whereas connection points 441 are exposed to the interior surface of the substrate through holes 461.

The use of wire bonding provides a simple way to connect the connection points of the trace portions, and avoids the need for particularly precise alignment of the substrate ends 425 and 421. The wire bonding process can compensate for reasonable amounts of misalignment between points to be connected, provided that the wire bonder is controlled by a machine vision system capable of detecting the misalignment and adjusting the configuration of the bonding wires to compensate for the same, so as to connect the correct points. In a variant of this approach, the roles of the first and second ends are reversed from that shown in FIG. 7. In a further variant, the second trace portions 443 are provided with connection points in the form of portions of the traces projecting beyond the end of the dielectric substrate, or projecting over holes in the dielectric substrate, so that these portions can be bent into engagement with the connection points of the first trace portions. The connection points may be thermosonically or ultrasonically bonded to one another in much the same way as leads on a tape automated bonding (TAB) tape are bonded to another element. In a further variant, the projecting leads may be temporarily supported to facilitate bonding. For example, the techniques shown in U.S. Pat. No. 5,915,752, the disclosure of which is hereby incorporated by reference, may be employed.

Numerous additional variations and combinations of the features discussed above can be utilized without departing from the scope of the present invention. In one such variant, the roles of the mounting terminals and connecting terminals discussed above are reversed. For example, the package of FIG. 4 may be mounted to a circuit board by connection terminals 34 and 36 additional microelectronic elements or packages can be connected to mounting terminals 30. Similarly, the connection terminals on the top run 24 can be used to mount the package to a circuit panel, so that the mounting terminals 30 face upwardly, away from the circuit panel. The mounting terminals can be used to connect an additional package or other element. Also, terminals other than the solder-bondable pads shown in the drawings, such as pins projecting from the substrate and adapted to be received in a socket, can be employed.

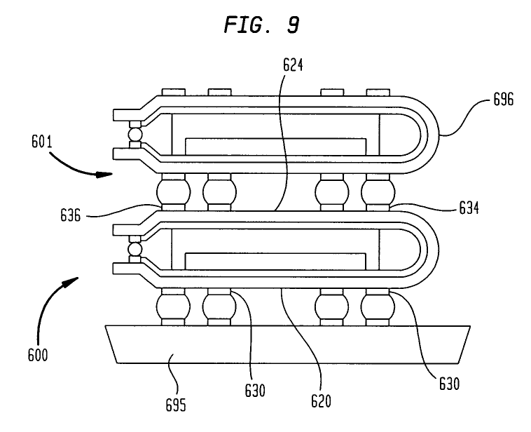

As shown in FIG. 8, any of the completed packages discussed above can be mounted to a circuit panel by bonding or otherwise connecting the mounting terminals 530 to contact pads 592 a circuit board 592. One or more further packaged or unpackaged microelectronic elements 590, 591 can be mounted on connection terminals 534 and 536. Although two separate elements 590, 591 are shown in FIG. 6, any number of elements can be mounted. The precise alignment of the connection terminals relative to one another is especially useful where a single element is mounted to all of the connection terminals. As shown in FIG. 9, where the mounting terminals 630 and the connection terminals 634 and 636 define identical arrays of terminals on top run 624 and bottom run 620 of a package 600, another package 601 of the same type can be mounted to the connecting terminals 634, 636, so that a plurality of identical packages can be stacked. In such a stack, the mounting terminals of each package are connected to the connection terminals of the next lower package in the stack. Thus, the stack can include more than the two packages shown in FIG. 9. The mounting terminals 630 of the bottom package 600 are used to connect the stack to a circuit panel 695 or other substrate.

Although the connections to connection terminals and mounting terminals are shown utilizing bonding material, such as solder, these connections can be formed utilizing any conventional technique known in the art. The additional elements or packages can be mounted to the connection terminals before or after the package is mounted to the circuit panel.

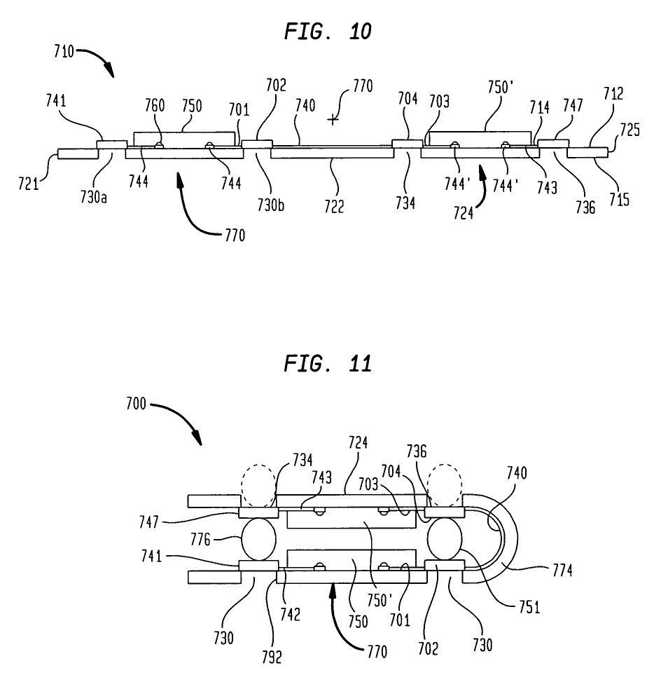

In a package 700 (FIGS. 10 and 11) according to yet another embodiment of the present invention, the metallic elements such as the trace portions, terminals and connection points are disposed on the interior surface 712 of the dielectric substrate. Here again, the substrate has first trace portions 742 connected to at least some of a set of device pads 744 disposed on the first region 720 of the substrate. The connection points 741 for the first trace portions 742, near the first end 721 of the first substrate portion 720, are exposed to the exterior surface of the dielectric element through holes in the dielectric element so that the connection points 741 also form some of the mounting terminals 730a. As in the embodiment discussed above with reference to FIGS. 1-4, the structure includes second trace portions 743 disposed on the second region 724 of the substrate. These second trace portions have connection points 747 near the second end 725 of the substrate. Connection points 747 are exposed to the exterior surface 716 of the substrate so that these connection points form a set of connection terminals 736. Also, a second set of device pads 744′ is disposed on the second region 724 of the substrate, and some or all of the second device terminals 744′ are connected to second trace portions 743.

The package further includes a third set of trace portions 701 on the first region of the substrate. Trace portions 701 are also connected to some of the first device pads 744 on the first region 720. Trace portions 701 have connection points 702 disposed on the first region 720. Connection points 702 of the third set are closer to the center portion 722 than connection points 741 of the first set, but still outside of the center region. Connection points 702 are also exposed to the exterior surface, so as to form additional mounting terminals 730b.

A fourth set of trace portions 703 has connection points 704 disposed on the second region 724, closer to center region 722 than connection points 747 of the second set. Connection points 704 are exposed to the exterior surface 716 so that these connection points form connection terminals 734. Trace portions 703 desirably are connected to some of the second device pads 744′.

Here again, the substrate carries fold-side traces 740 extending from the first region 720, across center region 722, to second region 724. The fold-side traces interconnect some of the conductive elements on the first region 720, such as mounting terminals 730 and device pads 744, with some of the conductive elements on second region 724, such as connection terminals 734,736 and device pads 744′.

The package also includes two microelectronic devices 750 and 750′ are disposed on the interior surface 714 of the dielectric element 712. In the particular embodiment depicted, each microelectronic element includes a chip mounted in a “face-down” orientation, with the contacts 760 of the chip facing toward the interior surface 712 of the substrate. The substrate may be folded along longitudinal axis 770, seen in end view in FIG. 10, in order to create the geometric shape shown in FIG. 11. Once in this folded position, the two microelectronic elements 750 and 750′ are both housed within cavity 792 defined by the folded substrate, with the rear or non-contact-bearing surfaces of the chips facing confronting one another.

Here again, the connection points 741 and 747 of the first and second trace portions are connected to one another, as by bonding material masses 776, thereby merging some or all of the first trace portions 742 and second trace portions 743 into composite traces. Similarly, some or all of the third trace portions 701 and fourth trace portions 703 are merged into composite traces by third connection points 702 and fourth connection points 704 to one another, as by bonding material masses 751. These connections are also made outside of fold 774, without use of the fold-side traces 740 extending across the fold.

The package thus provides numerous routes for connectivity between the two microelectronic elements 750, 750′, as well as between the mounting terminals 730 and the connection terminals 734, 736. Packages according to this arrangement can be stacked or connected to further elements using the connection terminals 734, 736 in the manner described above. The connection points and bonding material masses provide short, low-impedance connections within the stack. In a variant, particularly useful in the case of memory chips, the connections through the bonded connection points can provide vertical columns in the stack such that corresponding contacts on several chips in the stack are connected to the same column. The connections through the fold-side traces 740 can be used to provide “jogs” or offsets in the connection paths, so that unique signal paths are provided to individual chips in the stack. Such unique signal paths can be used to convey chip select signals.

The arrangement shown in FIGS. 10 and 11 can be varied in the ways discussed above as, for example, by using different types of interconnections between the connection points of the trace portions. The conductive elements can be disposed on the exterior surface 716 of the dielectric element, or within the thickness of the dielectric element. In a further variant, the mounting terminals and connection terminals can be formed separately from the connection points. In another variant, the fold-side traces may be omitted.

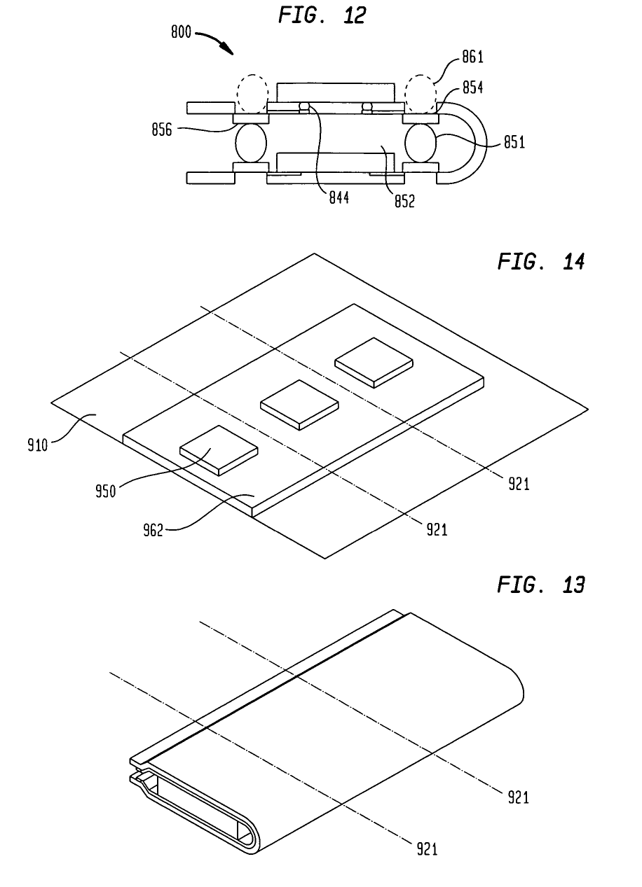

In yet another variant (FIG. 12), a first microelectronic element 850 is disposed over interior surface 814 of dielectric element 812, and hence is disposed within the cavity 892 of the package in the folded condition. Before or after folding, a second microelectronic element 850′ is disposed on the exterior surface 816 of the dielectric element 812, before or after folding. The second microelectronic element is mounted to second device pads 844′, which are exposed to the exterior surface. The second microelectronic element is disposed outside of cavity 892, but leaves connection terminals 834, 836 unobstructed. As with the previous embodiment, electrical connections such as solder balls 861, shown in phantom view, may connect the connection terminals of the microelectronic package 800 to an additional electronic package or chip. The solder balls desirably project above the second microelectronic element 850.

The manufacturing processes discussed above can be varied so as to form numerous packages at once. For example, a plurality of devices 950 (FIG. 13) may be disposed on a single substrate 910 in the form of a strip, sheet or tape. These devices may be covered by a unitary overmolding 962. The substrate is folded and subjected to other operations as discussed above, to form a large assembly as shown in FIG. 14. The assembly may be severed, as by cutting along one or more of lines 921, so as to separate portions of the folded assembly from one another and form individual units. Each unit includes one or more of the microelectronic devices 950 and the associated portions of the folded substrate 910. The substrate can be severed along further lines so as to trim off undesired portions of the substrate, or fewer lines so as to include more than one element of the device in the package with the folded substrate.

Although the present invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A microelectronic package comprising:
a) a dielectric element having a fold, a first run and a second run, said dielectric element having a first region on said first run outside of said fold and having a second region on said second run outside of said fold, said first and second runs defining a cavity;
b) a first microelectronic device disposed within said cavity; and
c) a plurality of traces disposed on said dielectric element, at least some of said traces being composite traces, each such composite trace including a first portion extending in said first region and having a first connection point in said first region and a second portion extending in said second region and having a second connection point in said second region, said connection points being outside of said fold, wherein at least some of said first connection points are connected to some of said second connection points.

2. A microelectronic package according to claim 1, wherein said connections between said first and second connection points include masses of a bonding material.

3. A microelectronic package according to claim 1, wherein said connections between said first and second connection points include wire bonds.

4. A microelectronic package according to claim 1, further comprising a plurality of mounting terminals disposed on said first run.

5. A microelectronic package according to claim 4, further comprising a circuit panel, said circuit panel being connected to at least some of said mounting terminals.

6 A microelectronic package according to claim 4 further comprising a plurality of connection terminals disposed on said second run.

7. A microelectronic assembly including a package according to claim 6, further comprising a first additional microelectronic element, said first additional microelectronic element being connected to at least some of said plurality of connection terminals.

8. A microelectronic package according to claim 7 wherein said first additional microelectronic element is a microelectronic package.

9. A microelectronic package according to claim 6, wherein at least some of said plurality of traces are connected to at least some of said terminals.

10. A microelectronic package according to claim 9, wherein at least some of said plurality of said traces interconnect said first microelectronic device with at least some of said terminals.

11. A microelectronic package according to claim 1, wherein said plurality of traces includes fold-side traces extending across said fold between said first and second region.

12. A microelectronic package according to claim 1, wherein said first and second connection points are remote from said fold.

13. A microelectronic package according to claim 12 wherein said plurality of traces include additional composite traces, said additional composite traces including third trace portions extending in said first region and having third connection points, fourth trace portions extending in said second region and having fourth connection points, said third and fourth connection points being interconnected with one another outside of said fold, said third and fourth connection points being closer to said fold than said first and second connection points.

14. A microelectronic package according to claim 13 wherein said first microelectronic device is disposed between the interconnected first and second connection points and the interconnected third and fourth connection points.

15. A microelectronic package according to claim 1 wherein said first microelectronic device is disposed between the interconnected first and second connection points and said fold.

16. A microelectronic package according to claim 1, wherein an adhesive bond locks said second run to said first run.

17. A microelectronic package according to claim 1, further comprising a mass of encapsulant at least partially covering said first microelectronic device.

18. A microelectronic package according to claim 17, wherein said mass of encapsulant has a top surface facing said second run, and wherein said adhesive bond is formed between said top surface of said mass of encapsulant and said second run of said dielectric element.

19. A microelectronic package according to claim 1 further comprising a second microelectronic device, at least some of said plurality of traces interconnecting said first and second microelectronic devices with one another.

20. A microelectronic package according to claim 16, wherein said second microelectronic device is disposed within said cavity.

21. A microelectronic package according to claim 16, wherein said first additional microelectronic element is disposed outside of said cavity.

22. A method of making a microelectronic package comprising the steps of:
a) folding a dielectric substrate having first and second trace portions in first and second regions so as to form a fold and position the first and second regions facing one another so as to define first and second runs of the folded substrate; and
b) connecting said first and second trace portions to one another outside of said fold so as to form composite traces.

23. A method as claimed in claim 22 wherein said substrate has fold-side traces in a central region, said folding step being performed so as to bend said central region, whereby said fold-side traces extend between said first and second runs after said folding step.

24. A method as claimed in claim 22 further comprising mounting a first microelectronic device to said substrate and connecting said first microelectronic device to at least some of said first trace portions prior to said folding step, said folding step being performed so as to position said first microelectronic device in a cavity between said runs.
